(19) United States
(12) Patent Application Publication
(10) Pub. No.: US 2015/0248952 A1
(43) Pub. Date: Sep. 3, 2015

(54) HIGH-TEMPERATURE SUPERCONDUCTING WIRE MATERIAL

(71) Applicant: KOREA ELECTROTECHNOLOGY RESEARCH INSTITUTE, Changwon-si (KR)

(72) Inventors: Rock-kil Ko, Changwon-si (KR); Myung-hwan Sohn, Busan (KR); Young-sik Jo, Gimhae-si (KR); Dong-woo Ha, Changwon-si (KR); Boo-min Kang, Busan (KR); Dong-hyuk Kim, Taebaek-si (KR)

(73) Assignee: KOREA ELECTROTECHNOLOGY RESEARCH INSTITUTE

(21) Appl. No.: 14/713,233

(22) Filed: May 15, 2015

Related U.S. Application Data
(63) Continuation of application No. PCT/KR2013/005329, filed on Jun. 18, 2013.

(30) Foreign Application Priority Data
Nov. 26, 2012 (KR) 10-2012-0134793

(51) Int. Cl. H01B 12/06; H01L 39/24; H01B 13/00; H01L 39/12

(52) U.S. Cl. CPC H01B 12/06; H01L 39/12; H01L 39/24; H01B 13/0036

(57) ABSTRACT

A high-temperature superconducting wire material comprising: a pre-superconducting wire material layer formed by forcibly removing a metal substrate from a superconducting wire material formed by including the metal substrate, a buffer layer formed on the upper surface of the metal substrate and a superconducting conductive layer formed on the upper surface of the buffer layer; a silver (Ag) protective layer formed on the lower surface of the pre-superconducting wire material layer; and a copper (Cu) protective layer formed on the lower surface of the Ag protective layer. Since a superconducting wire material is formed by stripping a metal substrate of a second-generation high-temperature superconducting wire material and forming a metal protective layer, advantages include the reduction of a magnetization loss due to the magnetism of the substrate, excellent stability of the wire material, and increases in Je (engineering current density) due to the minimization of the thickness of the superconducting wire material.

### REFERENCE TO RELATED APPLICATIONS

This is a continuation of pending International Patent Application PCT/KR2013/005329 filed on Jun. 18, 2013, which designates the United States and claims priority of Korean Patent Application No. 10-2012-0134793 filed on Nov. 26, 2012, the entire contents of which are incorporated herein by reference.

### FIELD OF THE INVENTION

The present invention relates to a high-temperature superconducting wire material and, more particularly, to a high-temperature superconducting wire material, wherein a superconducting wire material having no metal substrate is formed by removing a metal substrate through interfacial debonding between the metal substrate and a superconducting layer of a second-generation high-temperature superconducting wire material and then forming a metal protective layer on the exposed superconducting layer, ultimately enabling magnetization loss to decrease due to the removal of the substrate having a magnetic component, exhibiting superior stability of the wire material, and increasing Je (engineering current density) owing to the minimization of the thickness of the superconducting wire material.

### BACKGROUND OF THE INVENTION

For a high-temperature superconducting wire material, a second-generation high-temperature superconducting wire material in tape form has been mainly employed and is currently widely useful.

As illustrated in FIG. 1, a YBCO- or (Re)BCO-based second-generation high-temperature superconducting wire material is configured such that a metal substrate 100 is disposed at the lower position, a buffer layer 110 having a multilayered metal oxide thin film is formed on the upper surface of the metal substrate 100, and a superconducting layer 210 as a metal oxide thin film is formed on the upper surface of the buffer layer.

Further, a metal protective layer is formed on the lower surface of the metal substrate 100 and the upper surface of the superconducting layer 210. The metal protective layer typically comprises an inner silver (Ag) protective layer and an outer copper (Cu) protective layer 220, resulting in a high-temperature superconducting wire material in tape form.

The second-generation high-temperature superconducting wire material essentially includes the metal substrate 100. The metal substrate is typically made of a magnetic metal, such as nickel or a nickel alloy.

The metal substrate 100 has a thickness of about 50-100 μm, and the buffer layer 110 has a thickness of about 0.2 μm. The superconducting layer 210 is about 1 μm thick, the Ag protective layer 220 is about 2 μm, and the Cu protective layer 230 is about 20 μm. Thus, the thickness of the metal substrate constitutes at least half the total thickness of the high-temperature superconducting wire material.

A high-temperature superconducting wire material having the above thickness and a width of 12 mm with a transport current of 330 A has Jc of 2.8 MA/cm². When the thickness of the metal substrate 100 is 50 μm, Je equals 28,887 A/cm², and when the thickness of the metal substrate 100 is 100 m, Je equals 18,939 A/cm².

As such, Jc (critical current density) is the transport current per unit area of a superconducting layer, and Je (engineering current density) is the transport current per total unit area of a superconducting wire material.

Since the metal substrate 100 is a magnetic body or has magnetic properties, the fabricated superconducting wire material exhibits magnetism and thus may cause magnetization loss upon application thereof. In high strong homogeneous magnetic field applications such as MRI or NMR, distortion of a uniform magnetic field is incurred.

A conventional superconducting wire material is problematic because any weak layer between the superconducting layer 210 including the buffer layer 110 and the metal substrate 100 may be easily debonded. Debonding of the superconducting wire material is caused between the metal substrate and the metal oxide thin film depending on a difference in thermal expansion between the metal substrate 100 and the thin film deposited thereon and on the interfacial state. Hence, in coil application fields, poor performance of wound superconducting coils and malfunctions thereof may occur.

In a typical high-temperature superconducting wire material, since the high-temperature superconducting layer, through which current is actually transported, is very thin to the level of about 1 μm, Jc (critical current density) showing transport current properties per thickness (more specifically, which is an area defined by the thickness and the width but only the thickness is mentioned taking into consideration the width being fixed to 4 mm or 10 mm) of the superconducting layer is as high as millions of A/cm². However, the ratio of the thickness of the metal substrate 100 relative to the total thickness of the wire material is high, and thus Je (critical engineering current density), which shows the transport current value per total thickness of the superconducting wire material and is regarded as important in terms of designs for practical applications, is no more than tens of thousands of A/cm².

### SUMMARY OF THE INVENTION

Accordingly, the present invention has been made keeping in mind the above problems occurring in the related art, and an object of the present invention is to provide a high-temperature superconducting wire material, wherein a superconducting wire material having no metal substrate is formed by removing a metal substrate through interfacial debonding between the metal substrate and a superconducting layer of a second-generation high-temperature superconducting wire material and then forming a metal protective layer on the exposed superconducting layer, ultimately enabling magnetization loss to decrease due to the removal of the substrate having a magnetic component, exhibiting superior stability of the wire material, and increasing in Je (engineering current density) owing to the minimization of the thickness of the superconducting wire material.

In order to accomplish the above object, the present invention provides a high-temperature superconducting wire material, comprising: a pre-superconducting wire material layer formed by forcibly removing a metal substrate from a superconducting wire material comprising the metal substrate, a buffer layer formed on an upper surface of the metal substrate, and a superconducting layer formed on an upper surface of the buffer layer; an Ag protective layer formed on a lower surface of the pre-superconducting wire material layer; and a Cu protective layer formed on a lower surface of the Ag protective layer.

The pre-superconducting wire material layer is preferably configured such that the Ag protective layer and the Cu protective layer are sequentially formed on an upper surface of the superconducting layer.

The buffer layer is preferably removed together with the metal substrate.

The metal substrate is preferably removed by welding the superconducting wire material to a metal tape plate and then separating the substrate.

The metal substrate is preferably removed by winding the separated metal substrate and the pre-superconducting wire material layer respectively on two rollers spaced apart from each other.

Therefore, as a superconducting wire material having no metal substrate is formed by removing a metal substrate through interfacial debonding between the metal substrate and a superconducting layer of a second-generation high-temperature superconducting wire material and then forming a metal protective layer on the exposed superconducting layer, a very small magnet having enhanced magnetic field uniformity can be manufactured. Furthermore, magnetization loss caused by the magnetic component of the metal substrate can be decreased, and superior thermal conductivity and stability can be exhibited. Moreover, there is no debonding phenomenon, and Je (engineering current density) as high as 2-3 times that of a conventional high-temperature superconducting wire material can result.

According to the present invention, a superconducting wire material having no metal substrate is manufactured by removing a metal substrate through interfacial debonding between the metal substrate and a superconducting layer of a second-generation high-temperature superconducting wire material and then forming a metal protective layer on the exposed superconducting layer. Because of removal of the metal substrate having a thickness of 50-100 μm from a conventional high-temperature superconducting wire material, Je is increased to 60,841 A/cm², which is 2-3 times the existing Je of 18,939-28,887 A/cm².

Thereby, a very small magnet having improved magnetic field uniformity can be manufactured, and magnetization loss can be decreased due to removal of the metal substrate having a magnetic component. Furthermore, thermal conductivity and stability can become superior, and there is no debonding phenomenon. Also, Je (engineering current density) of the high-temperature superconducting wire material according to the present invention is as high as 2-3 times that of a conventional high-temperature superconducting wire material.

### BRIEF DESCRIPTION OF THE DRAWINGS

FIG. 1 is a schematic cross-sectional view illustrating the structure of a conventional high-temperature superconducting wire material;

FIG. 2 is a schematic cross-sectional view illustrating a pre-superconducting wire material having no metal substrate according to an embodiment of the present invention;

FIG. 3 is a schematic cross-sectional view illustrating a high-temperature superconducting wire material according to an embodiment of the present invention;

FIG. 4 is a photograph illustrating a superconducting wire material as a known product according to an embodiment of the present invention;

FIG. 5 illustrates the configuration where a metal substrate is removed from the superconducting wire material of FIG. 4;

FIG. 6 illustrates the configuration where an Ag protective layer is formed on the superconducting wire material of FIG. 5;

FIG. 7 illustrates the configuration where a Cu protective layer is formed on the superconducting wire material of FIG. 6;

FIG. 8 is a photograph illustrating a sample for measurement of critical current, as manufactured using the high-temperature superconducting wire material of FIG. 7; and

FIG. 9 illustrates the results of measurement of critical current of the sample of FIG. 8.

### DETAILED DESCRIPTION OF THE INVENTION

Hereinafter, a detailed description will be given of preferred embodiments of the present invention with reference to the appended drawings.

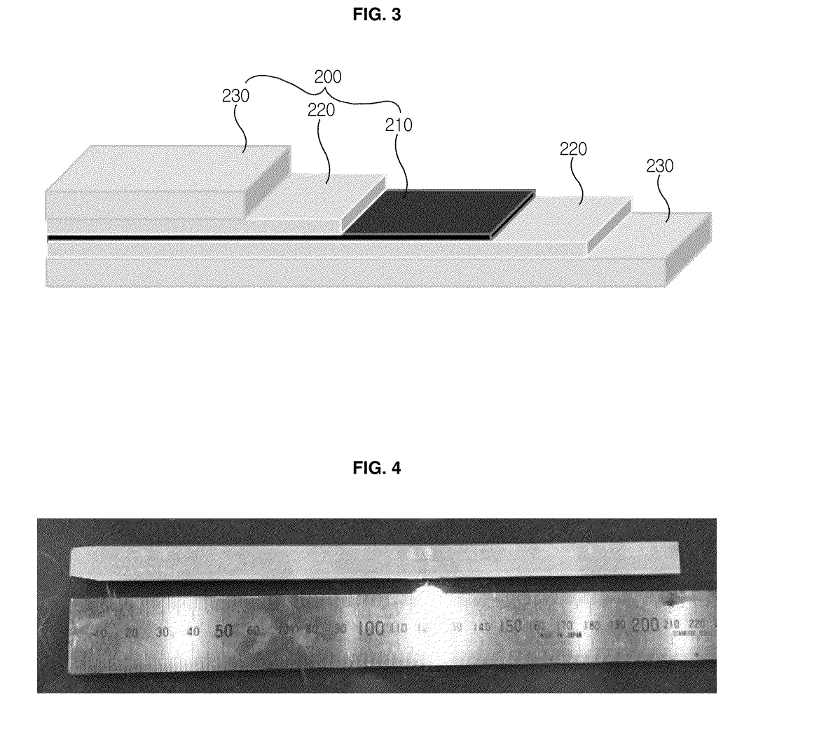

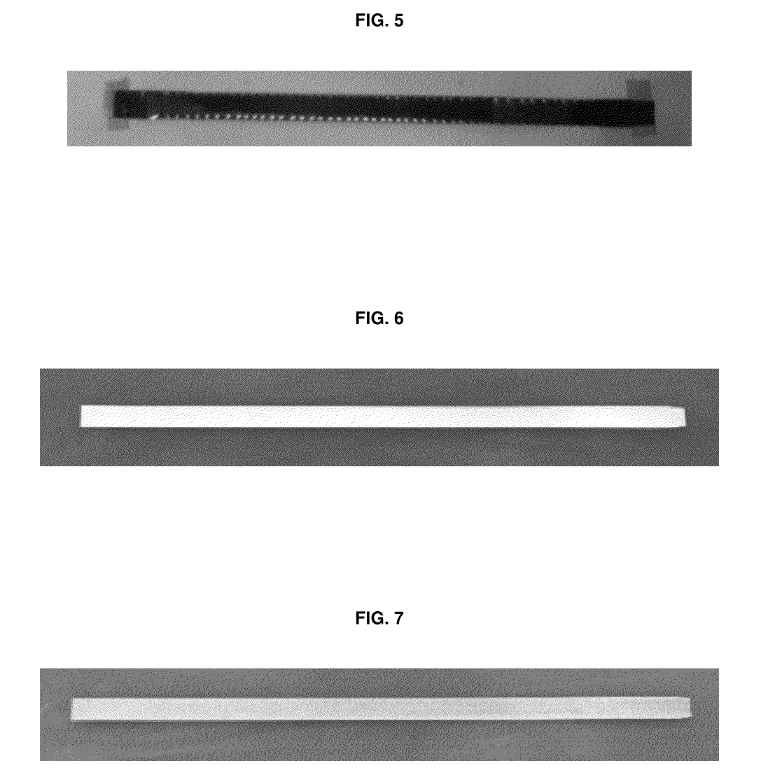

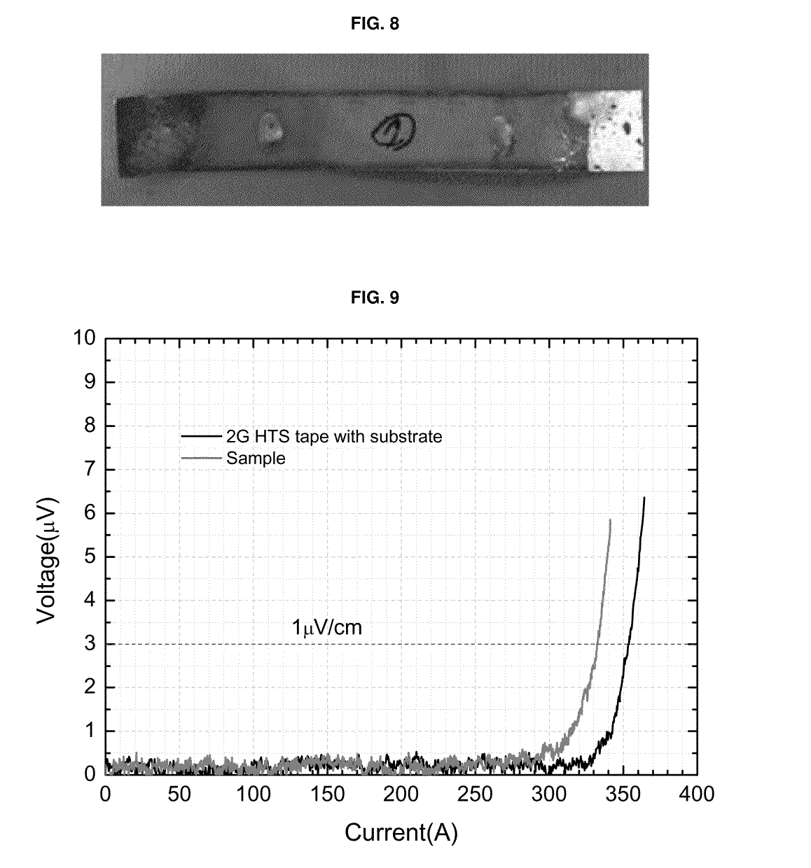

FIG. 2 is a schematic cross-sectional view illustrating a pre-superconducting wire material having no metal substrate according to an embodiment of the present invention, FIG. 3 is a schematic cross-sectional view illustrating a high-temperature superconducting wire material according to an embodiment of the present invention, FIG. 4 is a photograph illustrating a superconducting wire material as a known product according to an embodiment of the present invention, FIG. 5 illustrates the configuration where a metal substrate is removed from the superconducting wire material of FIG. 4, FIG. 6 illustrates the configuration where an Ag protective layer is formed on the superconducting wire material of FIG. 5, FIG. 7 illustrates the configuration where a Cu protective layer is formed on the superconducting wire material of FIG. 6, FIG. 8 is a photograph illustrating a sample for measurement of critical current as manufactured using the high-temperature superconducting wire material of FIG. 7, and FIG. 9 illustrates the results of measurement of critical current of the sample of FIG. 8.

As illustrated in the drawings, a high-temperature superconducting wire material according to the present invention is manufactured using a second-generation high-temperature superconducting wire material as a known product.

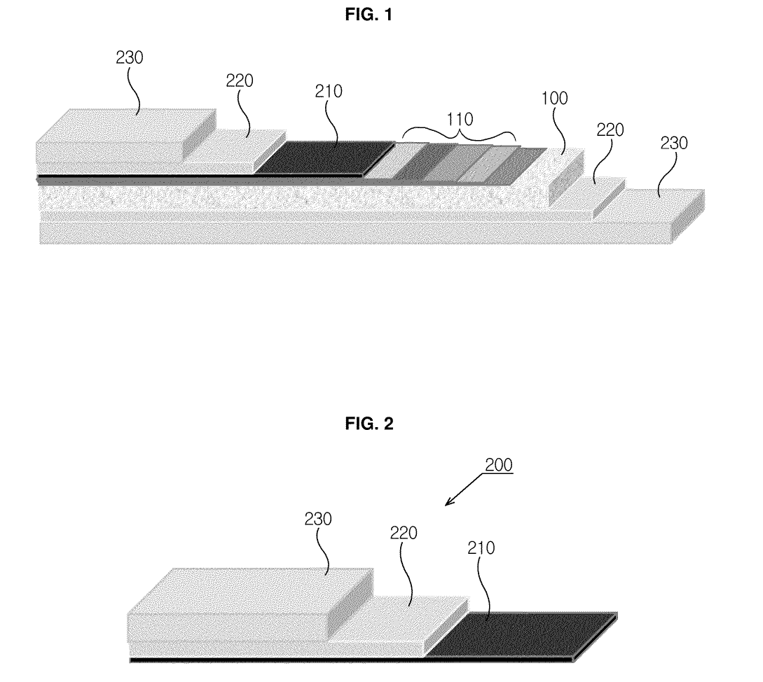

Specifically, a pre-superconducting wire material layer is first formed. The pre-superconducting wire material layer 200 is formed from a commercially available superconducting wire material in tape form having the structure as illustrated in FIG. 1.

A commercially available high-temperature superconducting wire material is purchased, and then attached to a copper or metal tape plate having predetermined mechanical strength with a predetermined thickness under the condition that a metal substrate of the wire material is disposed downwards, using a solder having a low melting point, such as InBi or InSn, after which the metal substrate is separated. As such, the Ag protective layer 220 and the Cu protective layer 230 positioned under the metal substrate 100 are debonded together with the metal substrate, thus forming a pre-superconducting wire material layer 200 according to the present invention as illustrated in FIG. 2. The pre-superconducting wire material layer 200 is configured such that the superconducting layer 210 is located at the lowermost position, and the Ag protective layer 220 and the Cu protective layer 220 are sequentially formed thereon.

For the pre-superconducting wire material layer, the buffer layer is debonded together with the metal substrate. In some cases, an MgO layer, which is an insulating layer formed the upper surface of the buffer layer, may be left behind on the pre-superconducting wire material layer.

To form the high-temperature superconducting wire material according to the present invention, the pre-superconducting wire material layer 200 is prepared, as shown in FIG. 2.

As mentioned above, the pre-superconducting wire material layer 200 is configured such that the superconducting layer 210 is provided at the lowermost position, and the Ag protective layer 220 and the Cu protective layer 220 are sequentially formed thereon.

Formed on the lower surface of the superconducting layer 210 of the pre-superconducting wire material layer 200 is the Ag protective layer 220. The Ag protective layer 220 is formed on the lower surface of the superconducting layer 210 using a sputtering process. The Ag protective layer 220 has a thickness of about 1.8 μm.

Formed on the lower surface of the Ag protective layer 220 is the Cu protective layer 230. The Cu protective layer 230 is provided in the form of a thin film by subjecting Cu to sputtering or plating on the lower surface of the Ag protective layer 220. The Cu protective layer 230 has a thickness of about 20 μm, thereby completing the high-temperature superconducting wire material having no metal substrate according to the present invention as shown in FIG. 3.

As necessary, a metal stiffener is laminated on both the upper and lower surfaces of the high-temperature superconducting wire material according to an embodiment of the present invention to form a laminate, thereby enhancing mechanical strength. The metal stiffener is typically exemplified by brass, Cu, or stainless steel.

When the superconducting wire material is long, it is disposed between two facing rollers to undergo debonding and formation of the Ag protective layer, the Cu protective layer and the laminate while corresponding constituents are separately wound on the two rollers.

The high-temperature superconducting wire material according to the present invention is manufactured as above. FIG. 4 illustrates a superconducting wire material as the known product of FIG. 1 according to an embodiment of the present invention. The known superconducting wire material is attached to a metal tape plate using an InBi solder, and then the metal substrate is removed. The wire material having no metal substrate is illustrated in FIG. 5.

FIG. 5 illustrates the pre-superconducting wire material layer from which the metal substrate and the buffer layer were removed. As mentioned above, the pre-superconducting wire material layer is configured such that the superconducting layer is located at the lowermost position, and the Ag protective layer and the Cu protective layer are sequentially formed thereon.

On the lower surface of the superconducting layer of the pre-superconducting wire material layer, the Ag protective layer is formed. By means of a sputtering process, the Ag protective layer is formed on the lower surface of the superconducting layer, which is illustrated in FIG. 6.

The Cu protective layer is formed on the lower surface of the Ag protective layer. The Cu protective layer is provided in the form of a thin film on the lower surface of the Ag protective layer using a sputtering process, thereby completing the high-temperature superconducting wire material according to the present invention.

A portion of the high-temperature superconducting wire material of FIG. 7 is cut and measured for current-voltage properties. Specifically, the high-temperature superconducting wire material of FIG. 7 was cut to a length of 7 cm, electrodes were formed thereon as shown in FIG. 8, and critical current was measured.

FIG. 9 illustrates the results of measurement of critical current of the high-temperature superconducting wire material according to the present invention, together with the critical current value of the comparative known superconducting wire material having a metal substrate.

As illustrated in FIG. 9, the critical current of the high-temperature superconducting wire material according to the present invention is about 335 A, which is regarded as good.

However, the sample according to the present invention has a critical current value lower than that of the known superconducting wire material. This is considered to be because, in the course of separation of the metal substrate during manufacturing the sample of the invention, the edge thereof is not well separated, and thus the width of the resulting high-temperature superconducting wire material having no edge is reduced, thus lowering the critical current.

As described hereinbefore, a superconducting wire material having no metal substrate according to the present invention is manufactured by removing a metal substrate through interfacial debonding between the metal substrate and a superconducting layer of a second-generation high-temperature superconducting wire material and then forming a metal protective layer on the exposed superconducting layer. Thereby, a very small magnet having improved magnetic field uniformity can be manufactured, and magnetization loss caused by the magnetic component of the metal substrate can be decreased. Furthermore, thermal conductivity and stability can become superior, and there is no debonding phenomenon. Moreover, Je (engineering current density) of the high-temperature superconducting wire material according to the present invention is as high as 2-3 times that of a conventional high-temperature superconducting wire material.

The present invention pertains to a high-temperature superconducting wire material and, more particularly, to a high-temperature superconducting wire material, wherein a superconducting wire material having no metal substrate is formed by removing a metal substrate through interfacial debonding between the metal substrate and a superconducting layer of a second-generation high-temperature superconducting wire material and then forming a metal protective layer on the exposed superconducting layer, ultimately enabling magnetization loss to decrease due to the removal of the substrate having a magnetic component, manifesting superior stability of the wire material, and increasing Je (engineering current density) owing to the minimization of the thickness of the superconducting wire material.

1. A high-temperature superconducting wire material, comprising:
a pre-superconducting wire material layer formed by forcibly removing a metal substrate from a superconducting wire material comprising the metal substrate, a buffer layer formed on an upper surface of the metal substrate, and a superconducting layer formed on an upper surface of the buffer layer;
a silver (Ag) protective layer formed on a lower surface of the pre-superconducting wire material layer; and
a copper (Cu) protective layer formed on a lower surface of the Ag protective layer.

2. The high-temperature superconducting wire material of claim 1, wherein the pre-superconducting wire material layer is configured such that the Ag protective layer and the Cu protective layer are sequentially formed on an upper surface of the superconducting layer.

3. The high-temperature superconducting wire material of claim 1, wherein the buffer layer is removed together with the metal substrate.

4. The high-temperature superconducting wire material of claim 3, wherein the metal substrate is removed by welding the superconducting wire material to a metal tape plate and then separating the substrate.

5. The high-temperature superconducting wire material of claim 3, wherein the metal substrate is removed by winding the separated metal substrate and the pre-superconducting wire material layer respectively on two rollers spaced apart from each other.
